(19) United States
(12) Patent Application Publication
(10) Pub. No.: US 2024/0258197 A1
(43) Pub. Date: Aug. 1, 2024

(54) METHODS AND ASSEMBLIES FOR COOLING SEMICONDUCTOR DEVICES USING CARBON ALLOTROPES

(71) Applicant: Qorvo US, Inc., Greensboro, NC (US)

(72) Inventors: Christo Bojkov, Plano, TX (US); Michael Roberg, Evergreen, CO (US); Zhi-Qi Li, Richardson, TX (US); Harold Isom, Plano, TX (US)

(21) Appl. No.: 18/161,235

(22) Filed: Jan. 30, 2023

(51) Int. Cl. H01L 23/373; H01L 23/522; H01L 23/532; H01L 23/66; H01L 29/16; H01L 29/20

(52) U.S. Cl. CPC H01L 23/3737; H01L 23/5226; H01L 23/53252; H01L 23/66; H01L 29/1608; H01L 29/2003; H01L 2223/6683

(57) ABSTRACT

Designs and methods of design of the present disclosure utilize various forms of carbon allotropes to form a carbon allotrope structure such as a graphene foam filling the interior cavity of vias that form part of a semiconductor die. The carbon allotrope structure enables heat generated within a GaN-based device region of the semiconductor die to be dissipated away. In a different embodiment, utilizing other forms of carbon allotropes, a carbon allotrope layer such as graphene layers is formed. The carbon allotrope layer is disposed over a frontside surface of the semiconductor die to provide additional heat dissipation paths for the heat generated within the GaN-based device region. The higher thermal conductivity of the carbon allotrope foam and the carbon allotrope layer allows the heat to be dissipated away from heat-generating semiconductor devices forming part of the device region of the semiconductor die.

### FIELD OF THE DISCLOSURE

The present disclosure generally relates to a field of semiconductor technology and particularly to designs and methods of design for thermal cooling of semiconductor devices.

### BACKGROUND

Gallium nitride (GaN)-based semiconductor devices are most frequently used in high-power and high-frequency integrated circuits such as monolithic microwave integrated circuits (MMICs) and radio frequency integrated circuits (RFICs). The self-heating of semiconductor devices in the device region of GaN-based semiconductor dies can lead to thermal overheating of the device region and the overall semiconductor devices, resulting in significant performance degradation. Therefore, there is a need for designs and methods of design that incorporate for thermal cooling of GaN-based semiconductor devices forming part of semiconductor dies.

### SUMMARY

In one aspect of the present disclosure, a semiconductor die comprising a die body having a substrate, a device region over the substrate, and at least one via is disclosed wherein the at least one via comprises at least one conductive wall structure defining an interior cavity. A carbon allotrope structure fills at least a portion of the interior cavity, wherein the carbon allotrope structure extends above and below an interface between the substrate and the device region. The carbon allotrope structure comprises a first carbon allotrope dispersed in one of a foam, an aerogel, a polymer, or a silicon-based membrane. The at least one conductive wall structure comprises a top side adjacent a frontside surface of the device region. The semiconductor die further comprises a first conductive layer over a backside surface of the substrate that forms at least a portion of the at least one conductive wall structure of the at least one via. The first conductive layer may comprise gold (Au).

The semiconductor die as disclosed further comprises a first metal interconnect over the frontside surface of the device region and in electrical contact with the top side of the at least one conductive wall. In an embodiment, the semiconductor die further comprises a semiconductor device formed in the device region and a carbon allotrope layer that covers at least a portion of the frontside surface of the device region such that the carbon allotrope layer covers the semiconductor device and the first metal interconnect. The thickness of the carbon allotrope layer is in the range of 5 μm to 200 μm. The carbon allotrope layer may comprise graphene layers. In an embodiment, the carbon allotrope layer comprises layers, films, flakes, fibers, or sheets of a second carbon allotrope.

The first carbon allotrope and the second carbon allotrope each comprise graphene, graphite, single-walled or multi-walled carbon nanotubes, or their combination, wherein the first carbon allotrope and the second carbon allotrope may each be functionalized with an oxide, a reduced oxide, a fluoride, a chloride, a bromide, an iodide, metals, metal oxides, metalloid oxides, or mixtures thereof. In an embodiment, the carbon allotrope structure comprises a graphene foam. The carbon allotrope structure may fill at least 90% of the interior cavity. In another embodiment, the carbon allotrope structure fills at least 75% of the interior cavity. In yet another embodiment, the carbon allotrope structure fills at least 50% of the interior cavity. At least 20% of the volume percentage of the carbon allotrope structure filling the interior cavity may extend above the interface formed between the substrate and the device region.

The substrate may comprise silicon carbide (SiC), the device region may comprise gallium nitride (GaN), or the substrate may comprise silicon carbide (SiC), and the device region may comprise gallium nitride (GaN). In an embodiment the device region comprises one or more layers of gallium nitride (GaN), aluminum gallium nitride (AlGaN), and aluminum nitride (AlN), wherein the substrate comprises one of sapphire, silicon carbide (SiC), gallium arsenide (GaAs), or silicon (Si). The semiconductor die may be a monolithic microwave integrated circuit (MMIC).

In a second aspect of the present disclosure, a semiconductor die comprises a die body having a substrate, a device region over the substrate, and a semiconductor device formed in the device region. A first metal interconnect forms over a frontside surface of the device region. A carbon allotrope layer that may cover at least a portion of the frontside surface such that the carbon allotrope layer covers the semiconductor device and the first metal interconnect. The thickness of the carbon allotrope layer is in the range of 5 μm to 200 μm.

The carbon allotrope layer may comprise graphene layers. In an embodiment the carbon allotrope layer comprises layers, films, flakes, fibers, or sheets of a carbon allotrope, while the carbon allotrope comprises graphene, graphite, single-walled or multi-walled carbon nanotubes, or their combination. The carbon allotrope may be functionalized with an oxide, a reduced oxide, a fluoride, a chloride, a bromide, an iodide, metals, metal oxides, metalloid oxides, or mixtures thereof.

In a third aspect of the present disclosure, a method is disclosed which comprises providing a die body comprising a substrate, a device region over the substrate, and at least one via, wherein the at least one via comprises at least one conductive wall structure defining an interior cavity, filling at least a portion of the interior cavity with a carbon allotrope precursor, and processing the carbon allotrope precursor to form a carbon allotrope structure filling at least a portion of the interior cavity, wherein the carbon allotrope structure extends above and below an interface between the substrate and the device region.

In a fourth aspect of the present disclosure, another method is disclosed that comprises providing a die body comprising a substrate, a device region over the substrate, forming a semiconductor device in the device region, depositing a first metal interconnect over a frontside surface of the device region, and depositing a carbon allotrope layer that covers at least a portion of the frontside surface such that the carbon allotrope layer covers the semiconductor device and the first metal interconnect.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 illustrates a sideview of an exemplary semiconductor die according to an embodiment of the present disclosure.

FIG. 2 illustrates a schematic sideview of the semiconductor die wherein each one of the at least the first via and the second via is partially filled with the carbon allotrope structure.

FIG. 3 shows the formation of the first thru-hole structure and the second thru-hole structure.

FIG. 4 illustrates the formation an adhesion layer.

FIG. 5 shows the electroplating of the first conductive layer over surfaces covered by the adhesion layer.

FIGS. 6A and 6B illustrate filling the first via V1 and the second via V2 with a carbon allotrope structure.

FIG. 7 shows the formation of the second conductive layer over the backside surface of the semiconductor die.

FIG. 8 shows the formation of the carbon allotrope layer over the frontside surface of the die body.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are merely intended to encompass different orientations of the device in addition to the orientation depicted in the Figures.

Furthermore, in the present disclosure, the term “same,” “substantially similar,” or “substantially equal” does not refer to an object that is identical but one that is “substantially the same,” “Substantially the same” as an object, for example, may refer to another object in which a difference between the two remains within a range of a manufacturing error.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

It is to be understood that the features of the various exemplary embodiments described herein may be combined with each other, unless specifically noted otherwise. Conversely, various features of the invention that are, for brevity, described in the context of a single embodiment, may also be provided separately or in any sub-combination. Specific embodiments described herein are merely illustrative of the present application and are not intended to limit the present application. This application is intended to cover any alternatives, modifications, and equivalents that may be included within the spirit and scope of the application as defined by the specification and the appended claims.

While gallium nitride (GaN) maintains a reliable operation at increased temperatures, dissipating the heat generated within a device region of a GaN-based semiconductor die remains an issue. At elevated voltages or high frequencies, the high energy associated with electrons in an active region of a semiconductor device is transferred into the lattice structure of the device region. The heat generated increases the temperature of the device region, which reduces the carrier mobility and causes a drop in the electron saturation velocity, leading to a reduced performance of the semiconductor device forming part of the semiconductor die.

The high thermal conductivity of carbon allotrope layers and structures and their incorporation into the manufacturing and fabrication of GaN-based semiconductor dies enables the heat generated within the GaN device region to be dissipated at an increased rate.

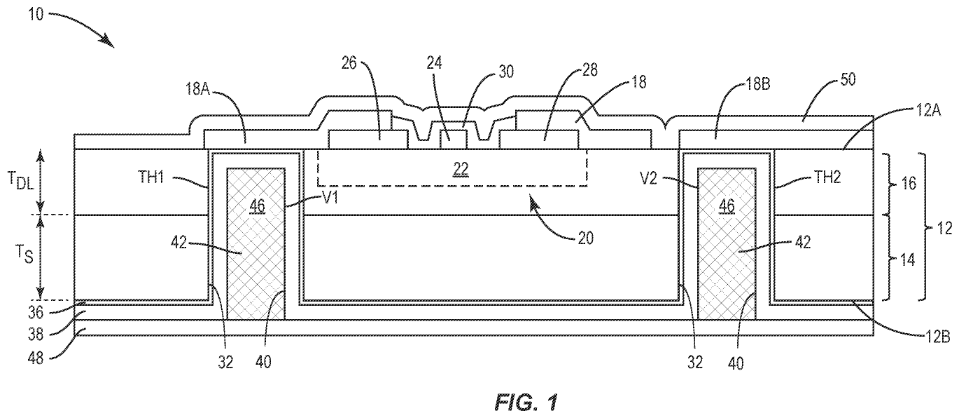

FIG. 1 illustrates a sideview of an exemplary semiconductor die 10 according to an embodiment of the present disclosure. The semiconductor die 10 comprises a die body 12 having a frontside surface 12A opposite to a backside surface 12B with respect to the die body 12. The die body 12 further comprises a substrate 14 and a device region 16. The device region 16 is disposed over the substrate 14 such that a surface of the device region 16 forms the frontside surface 12A and a surface of the substrate 14 forms backside surface 12B of the die body 12.

The substrate 14 may comprise one of sapphire, silicon carbide (SiC), gallium arsenide (GaAs), gallium nitride (GaN), silicon germanium (SiG), indium phosphide (InP), germanium (Ge), silicon (Si), or the like. In non-limiting embodiments, the substrate 14 may have a minimum thickness (T_{S}) of 50 μm, 75 μm, 100 μm, or 125 μm and a maximum thickness (T_{S}) of 425 μm, 450 μm, 475 μm, or 500 μm. The device region 16 may comprise one or more layers of III-V compound semiconductors, including semiconductor compound alloys containing elements from groups III and V in the periodic table including but not limited to GaN, aluminum gallium nitride (AlGaN), and aluminum nitride (AlN). In non-limiting embodiments, the device region 16 may have a minimum thickness (T_{DL}) of 10 μm, 15 μm, 20 μm, or 40 μm and a maximum thickness (T_{DL}) of 170 μm, 180 μm, 190 μm, or 200 μm. It should be appreciated that the die body 12 may further comprise additional layers disposed over the substrate 14 or forming part of the device region 16 that have not been introduced in the present disclosure for the simplicity of illustration. However, designs and methods of design described herein are not limited to the number, function, composition, or other characteristics of any additional layers that may form part of the die body 12. Those skilled in the art will recognize that the concepts described herein are applicable to various types of material systems other than those that are specifically mentioned herein.

In an embodiment, the semiconductor die 10 as shown in FIG. 1 is a monolithic microwave integrated circuit (MMIC) having a GaN-based device region 16 disposed over a SiC-based substrate 14. One or more semiconductor devices form in the device region 16 of the semiconductor die 10. The one or more semiconductor devices may comprise a high electron mobility transistor (HEMT) 20 as shown in FIG. 1. It should be appreciated that while only one semiconductor device (i.e., HEMT 20) is shown in FIG. 1, same designs and methods of design are applicable to any number and type of semiconductor devices including but not limited to field-effect transistors (FETs), diodes, power switches, power amplifiers, rectifiers, and regulators.

The HEMT 20 comprises an active region 22 formed in the device region 16. The active region 22 further comprises a source region, a drain region, and a gate region that are not shown here for the simplicity of the illustration. The HEMT 20 further comprises a gate contact 24, a source contact 26, and a drain contact 28 that are disposed over the frontside surface 12A of the die body 12. A dielectric layer 30 is deposited over a top surface of the HEMT 20. The dielectric layer 30 may be deposited over the gate contact 24, at least partially over the source contact 26 and the drain contact 28, and over a top surface of the active region 22. The dielectric layer 30 may comprise a passivation layer including a patterned surface passivation layer, a silicon dioxide (SiO₂) layer, a silicon nitride (SiN) layer, or the like. A silicon nitride (SiN) passivation layer may be deposited using a plasma-enhanced chemical vapor deposition (PECVD).

A plurality of metal interconnects 18 are disposed over the frontside surface 12A of the die body 12. The plurality of metal interconnects 18 comprises one of aluminum (Al), aluminum-copper (Al—Cu), copper (Cu), titanium (Ti), tungsten-titanium (TiW), tungsten (W), titanium nitride (TiN), palladium (Pd), gold (Au), or the like. The plurality of metal interconnects 18 comprises at least a first metal interconnect 18A and a second metal interconnect 18B. The first metal interconnect 18A forms an electrical contact with one of the gate contact 24, the source contact 26, or the drain contact 28 of the HEMT 20. The plurality of metal interconnects 18 may form metal-stacks or metal interconnect bridges that are not shown here for the simplicity of illustration.

The die body 12 further comprises a plurality of thru-holes comprising at least a first thru-hole TH1 and a second thru-hole TH2 each having an opening over the backside surface 12B of the die body 12 that extends through the die body 12 to the frontside surface 12A forming at least one wall structure 32. Bottom surfaces of the first metal interconnect 18A and the second metal interconnect 18B form part of top sides of the first thru-hole TH1 and the second thru-hole TH2.

An adhesion layer 36 is plated over the wall structure 32 of each of the first thru-hole TH1 and the second thru-hole TH2 and bottom surfaces of the first metal interconnect 18A and the second metal interconnect 18B forming a top wall of the wall structure 32 of each of the first thru-hole TH1 and the second TH2, and the exposed portions of the backside surface 12B.

A first conductive layer 38 is electroplated over surfaces covered by the adhesion layer 36 to form the first via V1 and the second via V2. It should be appreciated that while only two layers (i.e., the first conductive layer 38 and the adhesion layer 36) are illustrated in FIG. 1, additional layers may be disposed (at least partially) over surfaces covered or to be covered by the first conductive layer 38 or the adhesion layer 36. The designs and methods of design described herein are not limited to the number, function, composition, or other characteristics of any such additional layers.

A plurality of vias form part of the die body 12 and comprises at least a first via V1 and a second via V2 as shown in FIG. 1. It should be appreciated that while only two vias are shown in FIG. 1, same designs and methods of design are applicable to any number of vias and are irrespective of fabrication method used.

The first via V1 and the second via V2 are formed upon successive deposition of the adhesion layer 36 and the first conductive layer 38 over the wall structure 32 of each of the first thru-hole TH1 and the second thru-hole TH2 and bottom surfaces of the first metal interconnect 18A and the second metal interconnect 18B forming a top wall of the wall structure 32 of each of the first thru-hole TH1 and the second TH2.

Each of the first via V1 and the second via V2 comprises at least one conductive wall structure 40. The conductive wall structure 40 comprises one or more conductive sidewalls that define an interior cavity 42. The first metal interconnect 18A and the second metal interconnect 18B form electrical contacts with of top sides of interior cavities 42 of the first via V1 and the second via V2 wherein the interior cavities 42 are formed by the one or more sidewalls of conductive wall structures 40.

For the sake of convenience, in the present disclosure, a semiconductor die 10 having the configuration, features, and elements described thus far will hereinafter be referred to as a “die precursor.”

The first via V1 and the second via V2 having the configuration, features, and elements described thus far provide a narrow and limited path for the dissipation of the heat generated within the device region 16 of the die body 12. To improve the heat dissipation from the device region 16, the interior cavity 42 of each of the first via V1 and the second via V2 is at least partially filled with a carbon allotrope structure 46.

A second conductive layer 48 is deposited over the exposed areas of the first conductive layer 38 and over the exposed surfaces of the carbon allotrope structure 46 filling the interior cavity 42 of each of the first via V1 and the second via V2. The second conductive layer 48 forms a continuous and leveled conductive layer over the backside surface 12B of the die body 12 enabling a separate die, package base, or a heat sink interface to be attached.

The high thermal conductivity associated with the carbon allotrope structure 46 enables the first via V1 and the second via V2 to dissipate the heat generated within the device region 16 away and toward at least one of the frontside surface 12A, the backside surface 12B including the second conductive layer 48, or the substrate 14 of the die body 12.

The heat generated by the one or more semiconductor devices in the device region 16 at least partially dissipates toward the frontside surface 12A of the die body 12. In one embodiment, a carbon allotrope layer 50 is deposited over the frontside surface 12A of the die body 12 forming a unified and continuous layer, which enables heat generated and/or captured over the frontside surface 12A of the die body 12 to be further dissipated and distributed to areas away from the heat generating one or more semiconductor devices. In another embodiment, the carbon allotrope layer 50 is deposited in a pattern over the frontside surface 12A of the die body 12. Certain portions of the carbon allotrope layer 50 may be deposited over heat-generating areas. These portions will connect to other portions of the patterned carbon allotrope layer 50 to transfer and dissipate the generated heat to other areas of the frontside surface 12A that are away from the heat generating areas.

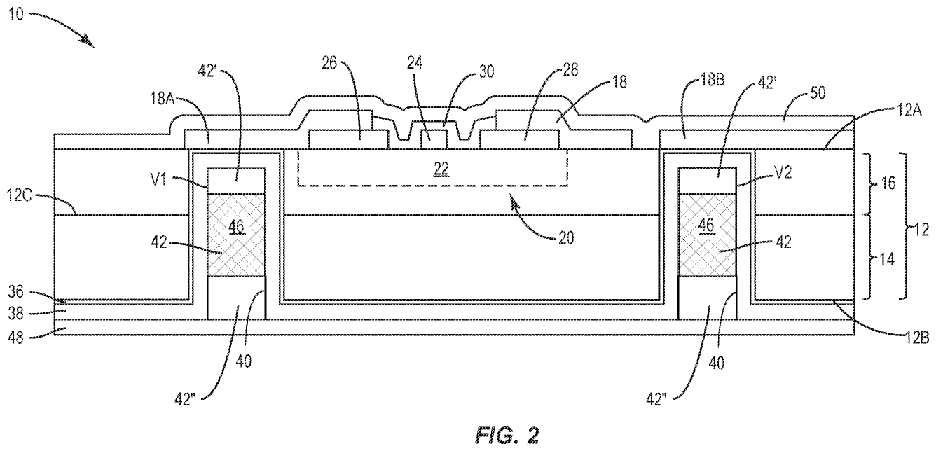

FIGS. 2 to 9 comprise a die precursor that is substantially similar to the die precursor as described in reference to FIG. 1. All elements as shown in FIGS. 2 to 9 with respect to the die precursor that were previously described in reference to FIG. 1 will continue to have the same reference numerals as those discussed.

FIG. 2 illustrates a schematic sideview of the semiconductor die 10 wherein each one of the at least the first via V1 and the second via V2 is partially filled with the carbon allotrope structure 46. Each of the first via V1 and the second via V2 comprises at least one conductive wall structure 40 defining an interior cavity 42. The carbon allotrope structure 46 fills at least a portion of the interior cavity 42 of each of the first via V1 and the second via V2. The carbon allotrope structure 46 extends above and below an interface 12C between the substrate 14 and the device region 16 of the die body 12.

The carbon allotrope structure 46 may fill one of at least 90%, 75%, or 50% of the interior volume of the interior cavity 42. The carbon allotrope structure 46 may fill at least a portion of the interior cavity 42 such that the carbon allotrope structure 46 extends above and below an interface 12C between the substrate 14 and the device region 16. In non-limiting embodiments, at least 20%, 30%, 40%, or 50% of the volume percentage of the carbon allotrope structure 46 filling the interior cavity 42 extends above the interface 12C formed between the substrate 14 and the device region 16.

A first unfilled portion of the interior cavity 42′ may be formed under bottom surfaces of a top wall of the at least one conductive wall structure 40 of each one of the first via V1 and the second via V2. The first unfilled portion of the interior cavity 42′ may form under bottom surfaces of a first metal interconnect 18A and a second metal interconnect 18B forming electrical contacts with the top wall of the at least one conductive wall structure 40 of each one of the first via V1 and the second via V2. The interior volume of the first unfilled portion of the interior cavity 42′ may comprise air or a desired gas.

A second unfilled portion of the interior cavity 42″ may be formed as part of the interior cavity 42 and under bottom surfaces the carbon allotrope structure 46 that fills a portion of the interior cavity 42 of each of the first via V1 and the second via V2. The interior volume of the second unfilled portion of the interior cavity 42″ may be filled with a metal comprising a first conductive layer 38 or a second conductive layer 48 or a material having a high thermal conductivity.

The second conductive layer 48 is deposited over the backside surface 12B of the die body 12 to form a continuous and leveled conductive layer over the backside surface 12B of the die body 12.

The partial filling of the first via V1 and the second via V2 with the carbon allotrope structure 46 such that the carbon allotrope structure 46 extends above and below the interface 12C between the substrate 14 and the device region 16 enables the heat generated in the device region 16 to be dissipated at a faster rate through the first via V1 and the second via V2 toward the substrate 14 having a higher thermal conductivity compared with the device region 16.

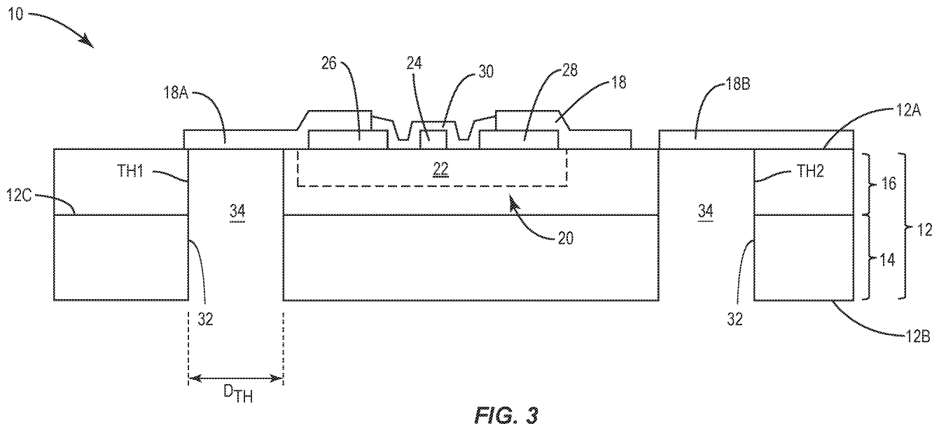

FIG. 3 shows the formation of the first thru-hole structure TH1 and the second thru-hole structure TH2. The die body 12 comprises at least one thru-hole structure forming an opening in the backside surface 12B of the die body 12 that extends through the substrate 14 and the device region 16 to the frontside surface 12A such that the wall structure 32 defines a cavity 34 of the thru-hole structure. In an embodiment, the wall structure 32 comprises one or more sidewalls that define a cavity 34 in the die body 12. The thru-hole may be round, rectangular, diamond shaped, elliptical, polygonal, or a combination thereof. In non-limiting embodiments, the thru-hole may have an opening diameter D_{TH} with a minimum D_{TH} of 10 μm, 15 μm, 20 μm, or 40 μm and a maximum D_{TH} of 170 μm, 180 μm, 190 μm, or 200 μm formed over the backside surface 12B of the die body 12.

The thru-hole structure as shown in FIG. 3 comprises a first thru-hole structure TH1 and a second thru-hole structure TH2. The first thru-hole structure TH1 and the second thru-hole structure TH2 each comprise at least one wall structure 32 defining a thru-hole cavity 34. The wall structure 32 comprises one or more sidewalls that define a cavity 34 in the die body 12. A bottom surface of the first metal interconnect 18A forms part of the wall structure 32 of the first thru-hole structure TH1 defining a top side of the thru-hole cavity 34 of the first thru-hole structure TH1. A bottom surface of the second metal interconnect 18B forms part of the wall structure 32 of the second thru-hole TH2 defining a top side of the thru-hole cavity 34 of the second thru-hole TH2. In an embodiment, sidewalls defining top sides of cavities 34 are adjacent to a frontside surface 12A of the die body 12

The first thru-hole TH1 and the second thru-hole TH2 may be formed in the SiC substrate 14 using an aluminum-based hard mask through a dry etching process or a lift-off process followed by the removal of aluminum-based mask using a chemical etching process. The first thru-hole TH1 and the second thru-hole TH2 are further extended through the GaN device region 16 using an inductively coupled plasma etching (reactive ion etching process) followed by a wet chemical etch to remove any residues. It should be appreciated that methods other than those outlined herein may be used to form the at least one thru-hole including the first thru-hole TH1 and the second thru-hole TH2.

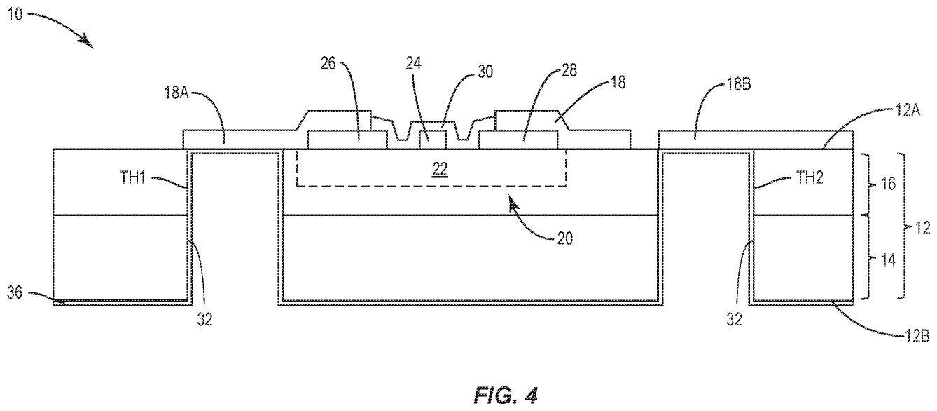

FIG. 4 illustrates the formation of the adhesion layer 36. The adhesion layer 36 may be a thin film of tungsten, chrome, niobium, or titanium or their alloys. In non-limiting embodiments, the adhesion layer 36 may have a minimum thickness of 0.5 μm and a maximum thickness of 5 μm. The adhesion layer 36 is configured as an intermediary metal interconnect for electroplating of the first conductive layer 38 (see FIG. 1). Using either one of the electroplating process or the electroless-plating process, a thin film of adhesion layer 36 is formed over the at least one wall structure 32 of the at least one thru-hole structure, bottom surfaces of metal interconnects 18 forming part of the wall structure 32 defining a top surface of the thru-hole structure, and the exposed portions of the backside surface 12B.

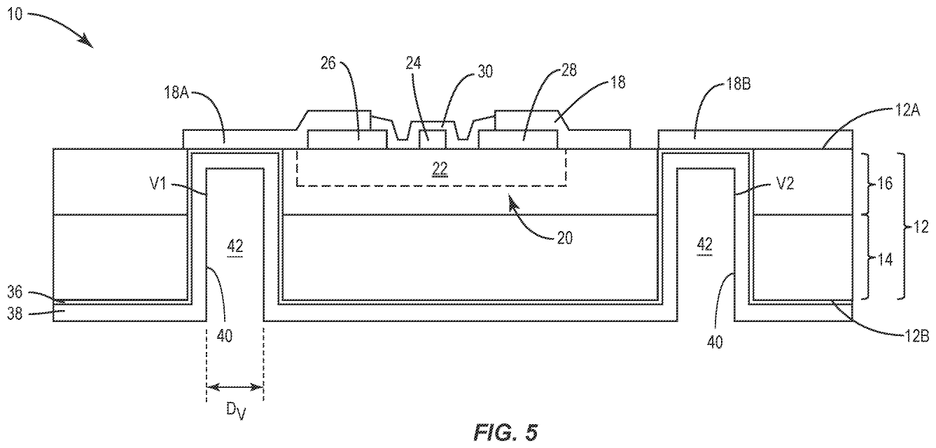

FIG. 5 shows the electroplating of the first conductive layer 38 over surfaces covered by the adhesion layer 36. The first conductive layer 38 comprises one of aluminum (Al), aluminum-copper (Al—Cu), copper (Cu), titanium (Ti), tungsten-titanium (TiW), tungsten (W), titanium nitride (TiN), palladium (Pd), gold (Au), or the like. In non-limiting embodiments, the first conductive layer 38 may have a minimum thickness of 1 μm and a maximum thickness of 150 μm.

In an embodiment, the first conductive layer 38 comprises gold (Au) with a thickness in the range of 0.5 μm to 5 μm. Maintaining a uniform deposition rate enables the first conductive layer 38 to be electroplated conformally and continuously over the adhesion layer 36 covering the at least one wall structure 32 of the at least one thru-hole structure.

The outer surface of the first conductive layer 38 forms part of the at least one conductive wall structure 40 which defines the interior cavity 42 of the at least one via. The at least one via comprises the first via V1 and the second via V2 each having an opening with a diameter D_{V} formed over the backside surface 12B of the die body 12. In non-limiting embodiments, the first via V1 and the second via V2 may have a minimum volume of 200 μm³, a maximum volume of 10,000 μm³, a minimum D_{V} of 50 μm, 60 μm, or 70 μm and a maximum D_{V} of 400 μm, 450 μm, or 500 μm.

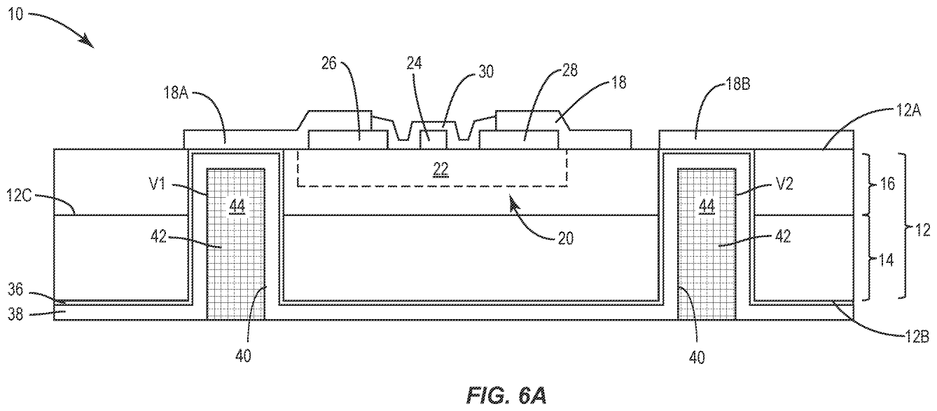

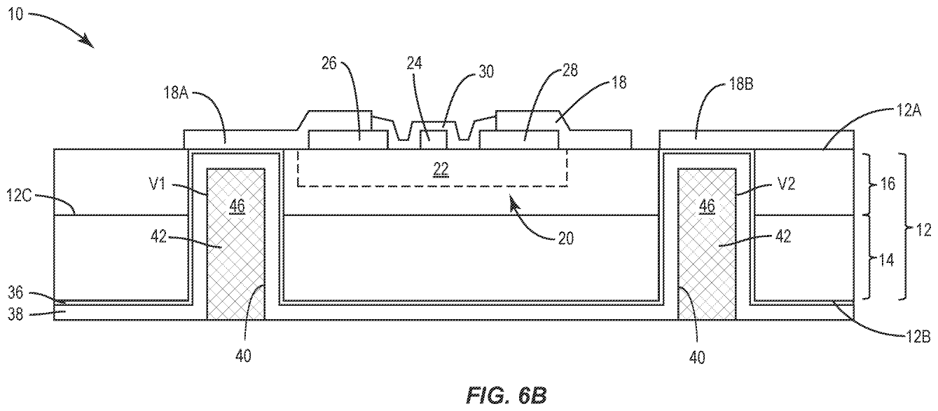

FIGS. 6A and 6B illustrate filling the first via V1 and the second via V2 with a carbon allotrope structure 46. The carbon allotrope structure 46 comprises a carbon allotrope dispersed in a matrix such as foam, sponge, aerogel, silica, polymer membrane, carbon black, composites of other carbon allotropes, ceramic, organic materials, metals, silicon-based membranes, or the like to form a three-dimensional high-porosity structure. The carbon allotropes include graphene, graphite, carbon fibers, carbon nanofibers, single-walled or multi-walled carbon nanotubes, C60, C70, C76, C82, and C84 fullerenes, amorphous carbon and carbon black, graphene nanoplatelet, pitch-based carbon fiber (PCF), expanded graphite (EG) or the like, or their combination with or without a functional group such as an oxide, a reduced oxide, a fluoride, a chloride, a bromide, an iodide, metals, metal oxides, metalloid oxides, or the like, or a mixture thereof.

According to certain methods described herein, one of carbon allotrope precursors 44 may fill the first via V1 and the second via V2 followed by a suitable treatment process resulting in the formation of carbon allotrope structure 46 within the interior cavity 42 of each of the first via V1 and the second via V2.

As shown in FIG. 6A, the first via V1 and the second via V2 are filled with one of carbon allotrope precursors 44. Carbon allotrope precursors 44 include but are not limited to a carbon allotrope solution, carbon allotrope hydrogel, carbon allotrope nickel composite, carbon allotrope composites of alumina, silica, titania, niobia, zirconia, zeolite, ceria, carbon-based materials, silicon carbide, aluminum phosphate, and hydrotalcite, or a colloidal suspension of polystyrene microspheres coated with the carbon allotrope. The filling of the first via V1 and the second via V2 with one of carbon allotrope precursors 44 is followed by a multistep process that may be repeated until the carbon allotrope structure 46 with a desired volume, density, and pore size is obtained. In non-limiting embodiments, the weight ratio of carbon allotrope to the carbon allotrope precursors 44 may be more than 30%, 40%, or 50%.

The process for the formation of the carbon allotrope structure 46 may be one or more of screen printing, spray application of solvent containing the allotropes, electroplating, hydrothermal drying of the carbon allotrope solution and/or hydrogel, chemical vapor deposition of a carbon allotrope over a nickel (Ni)-based skeleton (template) to form the carbon allotrope nickel composite followed by an etching process to remove the nickel, or drying of the colloidal suspension of polystyrene microspheres sacrificial template coated with a carbon allotrope-oxide.

FIG. 6B shows the first via V1 and the second via V2 filled with the carbon allotrope structure 46. The carbon allotrope structure 46 forms a three-dimensional interconnected porous material with unique physical properties. The carbon allotrope structure 46 may be a graphene foam. In non-limiting embodiments, the carbon allotrope structure 46 may have a minimum density of 30%, 40%, or 50% and a maximum density of 70%, 80%, or 90%. and an average pore size of 30 μm, 40 μm, 50 μm, or 60 μm.

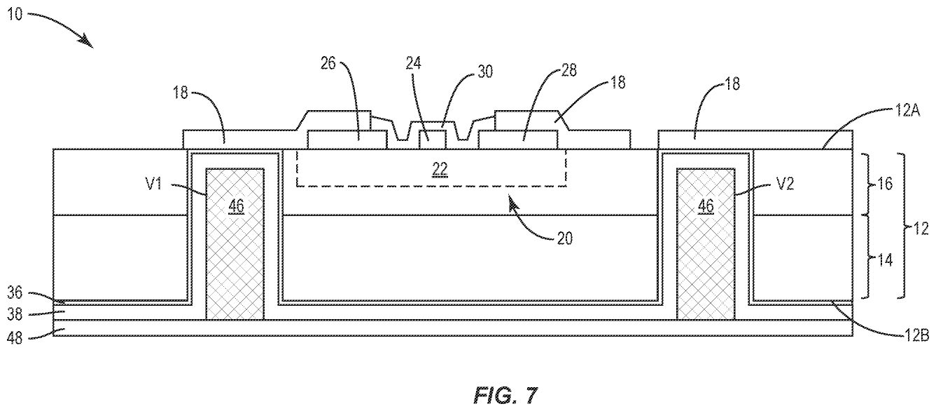

FIG. 7 shows the formation of the second conductive layer 48 over the backside surface 12B of semiconductor die 10. The second conductive layer 48 is deposited over the backside surface 12B of the die body 12 to form a leveled and unitary layer. The second conductive layer 48 comprises one of aluminum (Al), aluminum-copper (Al—Cu), copper (Cu), titanium (Ti), tungsten-titanium (TiW), tungsten (W), titanium nitride (TiN), palladium (Pd), gold (Au), or the like. In non-limiting embodiments, the second conductive layer 48 may have a minimum thickness of 5 μm, 10 μm or, 15 μm and a maximum thickness of 4,000 μm, 4,500 μm, or 5,000 μm.

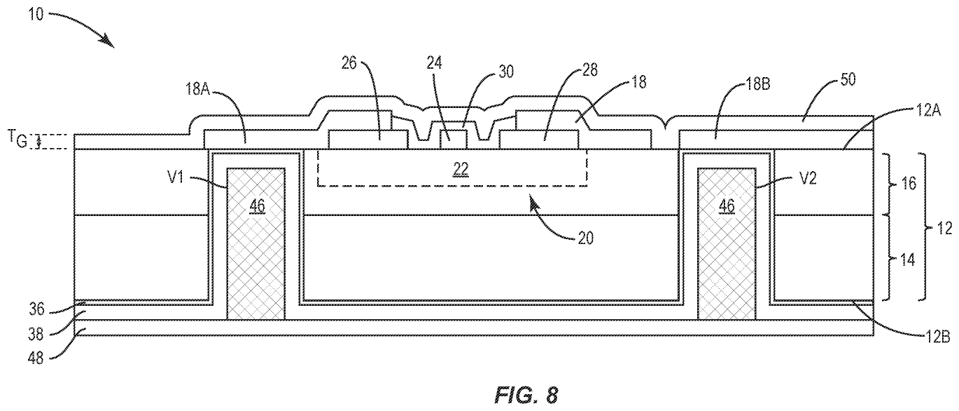

FIG. 8 shows the formation of the carbon allotrope layer 50 over the frontside surface 12A of the die body 12. The carbon allotrope layer 50 may form a direct contact with metal interconnects 18, top surfaces of the one or more semiconductor devices forming part of the semiconductor die 10, metal stacks (not shown), bridge metal interconnects (not shown), the dielectric layer 30, passivation layers (not shown), or other active or passive layers or devices forming part of the frontside surface 12A of the die body 12.

The carbon allotrope layer 50 comprises carbon allotrope sheets, layers, films, nanotubes, or fibers. The carbon allotrope includes graphene, graphite, carbon fibers, carbon nanofibers, single-walled or multi-walled carbon nanotubes, C60, C70, C76, C82, and C84 fullerenes, amorphous carbon and carbon black, graphene nanoplatelet, pitch-based carbon fiber (PCF), expanded graphite (EG) and the like, or their combination with or without a functional group such as an oxide, a reduced oxide, a fluoride, a chloride, a bromide, an iodide, metals, metal oxides, metalloid oxides, or mixtures thereof.

The thickness (T_{G}) of the carbon allotrope layer 50 may be non-uniform over the frontside surface 12A of the die body 12. In non-limiting embodiments, the thickness (T_{G}) of the carbon allotrope layer 50 may be not less than that 5 μm, 10 μm, or 15 μm and not more than that 4,000 μm, 4,500 μm, or 5,000 μm. The carbon allotrope layer 50 may partially cover the frontside surface 12A of the die body 12. According to an embodiment, a partial patterned or an unpatented coverage of the frontside surface 12A of the die body 12 may improve the heat dissipation over the frontside surface 12A of the semiconductor die 10. The carbon allotrope layer 50 may only cover the frontside surface 12A of the die body 12 in the areas surrounding the one or more of the semiconductor devices of the semiconductor die 10. In non-limiting embodiments, the partially covered area of the frontside surface 12A with the carbon allotrope layer 50 may be not less than 5%, 10%, 20% and not more than 75%, 85%, or 95% of a surface area of the frontside surface 12A.

The carbon allotrope layer 50 may be a graphene layer comprising one of one or more of graphene, graphene oxide, graphene reduced oxide, graphene fluoride, graphene chloride, graphene bromide, graphene iodide, and graphene nitrogenated, hydrogenated, or doped layers, films, or sheets. The carbon allotrope layer 50 may be deposited using screen printing method, spray application of solvent containing the allotropes and/or electroplating or any other method applicable in the industry. In an embodiment, The carbon allotrope layer 50 may be oppositely charged to a surface charge of the frontside surface 12A of the die body 12. Each of the carbon allotrope layer 50 and the frontside surface 12A of the die body 12 may be charged by one or more of a direct covalent attachment to a cationic group, a direct covalent attachment to an anionic group, forming a non-covalent complex with a surfactant that is cationically charged, or forming a non-covalent complex with a surfactant that is anionically charged. The carbon allotrope layer 50 is deposited over a frontside surface 12A the die such that an ionic bond between the two is formed.

The heat generated within the active region 22 of the HEMT 20 may be dissipated through one of at least two paths. The heat may partially flow within the device region 16 toward the frontside surface 12A of the die body 12, wherein the heat is dissipated away from HEMT 20 by the carbon allotrope layer 50. The heat may flow away from the heat-generating active region 22 and toward at least one of the first via V1 or the second via V2 formed in proximity of the HEMT 20 wherein that the heat is dissipated by the carbon allotrope structure 46 within the first via V1 or the second via V2 to one or more of the frontside surface 12A, the substrate 14, and the backside surface 12B. The carbon allotrope layer 50 provides heat flux paths to further distribute and dissipate the heat away from the HEMT 20.

It will be understood that sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A semiconductor die comprising:
a die body comprising a substrate, a device region over the substrate, and at least one via, wherein the at least one via comprises at least one conductive wall structure defining an interior cavity; and
a carbon allotrope structure filling at least a portion of the interior cavity, wherein the carbon allotrope structure extends above and below an interface between the substrate and the device region.

2. The semiconductor die of claim 1 wherein the carbon allotrope structure comprises a first carbon allotrope dispersed in one of a foam, an aerogel, a polymer, or a silicon-based membrane.

3. The semiconductor die of claim 2 wherein the at least one conductive wall structure comprises a top side adjacent a frontside surface of the device region.

4. The semiconductor die of claim 3 further comprising a first conductive layer over a backside surface of the substrate and forming at least a portion of the at least one conductive wall structure of the at least one via.

5. The semiconductor die of claim 4 wherein the first conductive layer comprises gold (Au).

6. The semiconductor die of claim 5 further comprising a first metal interconnect over the frontside surface of the device region and in electrical contact with the top side of the at least one conductive wall.

7. The semiconductor die of claim 6 further comprising:
a semiconductor device formed in the device region; and
a carbon allotrope layer that covers at least a portion of the frontside surface of the device region such that the carbon allotrope layer covers the semiconductor device and the first metal interconnect.

8. The semiconductor die claim 7 wherein the thickness of the carbon allotrope layer is in the range of 5 μm to 500 μm.

9. The semiconductor die of claim 7 wherein the carbon allotrope layer comprises graphene layers.

10. The semiconductor die of claim 7 wherein the carbon allotrope layer comprises layers, films, flakes, fibers or sheets of a second carbon allotrope.

11. The semiconductor die claim 10 wherein each of the first carbon allotrope and the second carbon allotrope comprises graphene, graphite, single-walled or multi-walled carbon nanotubes, or their combination.

12. The semiconductor die of claim 10 wherein each of the first carbon allotrope and the second carbon allotrope is functionalized with an oxide, reduced oxide, fluoride, chloride, bromide, iodide, metals, metal oxides, metalloid oxides, or mixtures thereof.

13. The apparatus of claim 1 wherein the carbon allotrope structure comprises a graphene foam.

14. The semiconductor die of claim 1 wherein the carbon allotrope structure fills at least 90% of the interior cavity.

15. The semiconductor die of claim 1 wherein the carbon allotrope structure fills at least 75% of the interior cavity.

16. The semiconductor die of claim 1 wherein the carbon allotrope structure fills at least 50% of the interior cavity.

17. The semiconductor die of claim 1 wherein at least 20% of the volume percentage of the carbon allotrope structure filling the interior cavity extends above the interface formed between the substrate and the device region.

18. The semiconductor die of claim 1 wherein the substrate comprises silicon carbide (SiC)

19. The semiconductor die of claim 1 wherein the device region comprises gallium nitride (GaN).

20. The semiconductor die of claim 1 wherein the substrate comprises silicon carbide (SiC) and the device region comprises gallium nitride (GaN).

21. The semiconductor die of claim 1 wherein the device region comprises one or more layers of gallium nitride (GaN), aluminum gallium nitride (AlGaN), and aluminum nitride (AlN) and wherein the substrate comprises one of sapphire, silicon carbide (SiC), gallium arsenide (GaAs), or silicon (Si).

22. The semiconductor die of claim 1 wherein the semiconductor die is a monolithic microwave integrated circuit (MMIC).

23. A semiconductor die comprising:
a die body comprising a substrate, a device region over the substrate; and
a semiconductor device formed in the device region;
a first metal interconnect over a frontside surface of the device region; and
a carbon allotrope layer that covers at least a portion of the frontside surface such that the carbon allotrope layer covers the semiconductor device and the first metal interconnect.

24. The semiconductor die claim 23 wherein the thickness of the carbon allotrope layer is in the range of 5 μm to 500 μm.

25. The semiconductor die of claim 23 wherein the carbon allotrope layer comprises graphene layers.

26. The semiconductor die of claim 23 wherein the carbon allotrope layer comprises layers, films, flakes, fibers or sheets of a carbon allotrope.

27. The semiconductor die claim 26 wherein the carbon allotrope comprises graphene, graphite, single-walled or multi-walled carbon nanotubes, or their combination.

28. The semiconductor die of claim 26 wherein the carbon allotrope is functionalized with an oxide, reduced oxide, fluoride, chloride, bromide, iodide, metals, metal oxides, metalloid oxides, or mixtures thereof.

29. A method comprising:
providing a die body comprising a substrate, a device region over the substrate, and at least one via, wherein the at least one via comprises at least one conductive wall structure defining an interior cavity;
filling at least a portion of the interior cavity with a carbon allotrope precursor; and
processing the carbon allotrope precursor to form a carbon allotrope structure filling at least a portion of the interior cavity, wherein the carbon allotrope structure extends above and below an interface between the substrate and the device region.

30. A method comprising:
providing a die body comprising a substrate, a device region over the substrate; and
forming a semiconductor device in the device region;
depositing a first metal interconnect over a frontside surface of the device region; and
depositing a carbon allotrope layer that covers at least a portion of the frontside surface such that the carbon allotrope layer covers the semiconductor device and the first metal interconnect.
